(19) United States
(12) Patent Application Publication
(10) Pub. No.: US 2015/0062838 A1
(43) Pub. Date: Mar. 5, 2015

(54) SYSTEM FOR ATTACHING DEVICES TO FLEXIBLE SUBSTRATES

(71) Applicants: Richard S. Speer, Concord, MA (US); David Hamby, Andover, MA (US); Adam M. Scotch, Amesbury, MA (US)

(72) Inventors: Richard S. Speer, Concord, MA (US); David Hamby, Andover, MA (US); Adam M. Scotch, Amesbury, MA (US)

(73) Assignee: OSRAM SYLVANIA Inc., Danvers, MA (US)

(21) Appl. No.: 14/017,439

(22) Filed: Sep. 4, 2013

(51) Int. Cl. H05K 3/10; H05K 3/00; H05K 13/04; H05K 1/18

(52) U.S. Cl. CPC H05K 3/10; H05K 1/189; H05K 3/0094; H05K 3/0044; H05K 13/04
USPC 361/749; 156/280; 156/253

(57) ABSTRACT

This disclosure is directed to a system for attaching devices to flexible substrates. A device may be coupled to a flexible substrate in a manner that prevents adhesive from contacting conductive ink while the adhesive is harmful. If conductive epoxy is used to anchor conductive pads in the device to the flexible substrate, conductive epoxy may be applied beyond the edge of the device over which conductive ink may be applied to make electrical connections. Holes may also be formed in the flexible substrate allowing conductive epoxy to be exposed on a surface of the flexible substrate opposite to the device location, the conductive ink connections being made on the opposite surface. The conductive ink may also be applied directly to the conductive pads when extended beyond the device's edge. The flexible substrate may be pre-printed with circuit paths, the conductive ink coupling the device to the circuit paths.

### TECHNICAL FIELD

The present invention relates to electronic assembly, and more specifically, to the placement of devices onto flexible substrates in a manner that avoids existing assembly issues. cl BACKGROUND

In a typical electronics manufacturing process, circuitry including, but not limited to, printed circuit boards, flexible substrates, packages such as multichip modules (MCM), etc. may be populated with electronic devices using pick-and-place operations. For example, the circuitry may be routed through machines equipped with vision systems for identifying device placement locations in the circuitry and manipulators configured to pick up devices from a supply location (e.g., rail, reel, etc.) and place the devices into the previously identified device locations. Pick-and-place manufacturing has been effective at least from the standpoint of accurately populating circuitry with a variety of devices at a speed substantially faster than manual device insertion.

An automated solder system usually follows pick-and-place operations, wherein the populated circuit board may be routed through a solder bath or reflow oven to permanently affix the components to the board. These processes involve high temperature, which may be tolerable for typical circuit board materials such as polytetrafluoroethylene (Teflon®), FR-4, FR-1, CEM-1 or CEM-3. However, flexible substrates using, for example, polyethylene terephthalate (PET) may be susceptible to damage by high heat, and thus, alternative manufacturing processes are required. Materials such as conductive epoxy (e.g., epoxy including silver) can be used to affix component devices to flexible substrates at a much lower temperature (e.g., enough heat to cure the epoxy). However, conductive epoxy can also be problematic. Emerging flexible substrate technology requires that the flexible substrate initially be printed (e.g., silk screened) with circuit traces based on conductive ink before devices are placed on the flexible substrate. Solvents and other chemicals that may be present in the conductive epoxy used to anchor the placed devices to the flexible substrate may cause the pre-printed conductive ink-based circuit traces to lose their adhesion to the flexible substrate (e.g., to delaminate), rendering the circuit assembly unusable.

### BRIEF DESCRIPTION OF THE DRAWINGS

Reference should be made to the following detailed description which should be read in conjunction with the following figures, wherein like numerals represent like parts:

FIG. 1 illustrates an example system for attaching devices to flexible substrates consistent with the present disclosure;

FIG. 2 illustrates an example adhesive to conductive ink-based connection consistent with the present disclosure;

FIG. 3 illustrates an alternative example adhesive to conductive ink-based connection consistent with the present disclosure;

FIG. 4 an example device to conductive ink-based connection consistent with the present disclosure consistent with the present disclosure;

FIG. 5 an example of circuit path to device bridging consistent with the present disclosure; and

FIG. 6 illustrates example operations for a system for attaching devices to flexible substrates consistent with the present disclosure.

Although the following Detailed Description will proceed with reference being made to illustrative embodiments, many alternatives, modifications and variations thereof will be apparent to those skilled in the art.

### DETAILED DESCRIPTION

This disclosure is directed to a system for attaching devices to flexible substrates. In general, a device may be coupled to a flexible substrate in a manner that prevents adhesive from contacting conductive ink when the adhesive is in a state possibly harmful to the conductive ink. Embodiments consistent with the present disclosure may vary depending on how the device is coupled to the flexible substrate. For example, if conductive epoxy is used to couple at least one conductive pad in the device to the flexible substrate, additional epoxy may be applied extending beyond an edge of the device, the extra epoxy providing a place over which conductive ink may later be applied to make electrical connections. It may also be possible for holes to be formed in the substrate, the holes allowing the conductive epoxy to be exposed on a surface of the flexible substrate opposite to where the device is coupled, the conductive ink connections being made on the opposite side. Non-conductive epoxy may also be employed in instances when conductive ink may be applied directly to at least one conductive pad extending beyond the device. In one embodiment, the flexible substrate may further be pre-printed with circuit paths, the conductive ink being applied to the flexible substrate to electrically couple the device with the circuit paths.

In one embodiment, example circuitry may comprise a flexible substrate, at least one device, adhesive and conductive ink. The adhesive may be applied to the flexible substrate to couple the at least one device to the flexible substrate. The conductive ink may then be applied to the flexible substrate to form conductors electronically coupled to the at least one device, the conductive ink being applied after the adhesive.

The adhesive may be cured before the conductive ink is applied to the flexible substrate. In one example implementation, the at least one device may comprise at least one conductive pad and the adhesive may be conductive epoxy anchoring the at least one device to the flexible substrate by adhering the at least one conductive pad to the flexible substrate. The conductive epoxy may be applied to the flexible substrate so that at least a portion of the conductive epoxy may be exposed beyond an edge of the at least one device when coupled to the flexible substrate. The conductive ink may be applied over at least part of the exposed portion of the conductive epoxy to form conductors electronically coupled to the at least one device.

In another example implementation, the flexible substrate may comprise an opening formed in a location on a surface of the flexible substrate corresponding to the at least one conductive pad when the at least one device is coupled to the flexible substrate, the opening traversing from the surface to an opposite surface of the flexible substrate, the conductive epoxy being applied to the flexible substrate to fill the opening so that the conductive epoxy is exposed on the opposite side of the flexible substrate when the at least one device is coupled to the flexible substrate. The conductive ink may then be applied to the opposite side of the flexible substrate and over the exposed conductive epoxy to form conductors electronically coupled to the at least one device.

In another example implementation, the at least one device may comprise at least one conductive pad including a portion extending beyond an edge of the at least one device and the adhesive is non-conductive epoxy to adhere the device to the flexible substrate. The conductive ink may then be applied over at least part of the portion of the at least one conductive pad extending beyond the edge of the at least one device to form conductors electronically coupled to the at least one device.

The example circuitry may further comprise at least one circuit path printed on the flexible substrate, the conductors coupling the at least one printed circuit path to the at least one device. A method consistent with various embodiments of the present disclosure may include, for example, applying adhesive to a flexible substrate, coupling at least one device comprising at least one conductive pad to the substrate using the adhesive and applying conductive ink to the flexible substrate to form conductors electronically coupled to the at least one device.

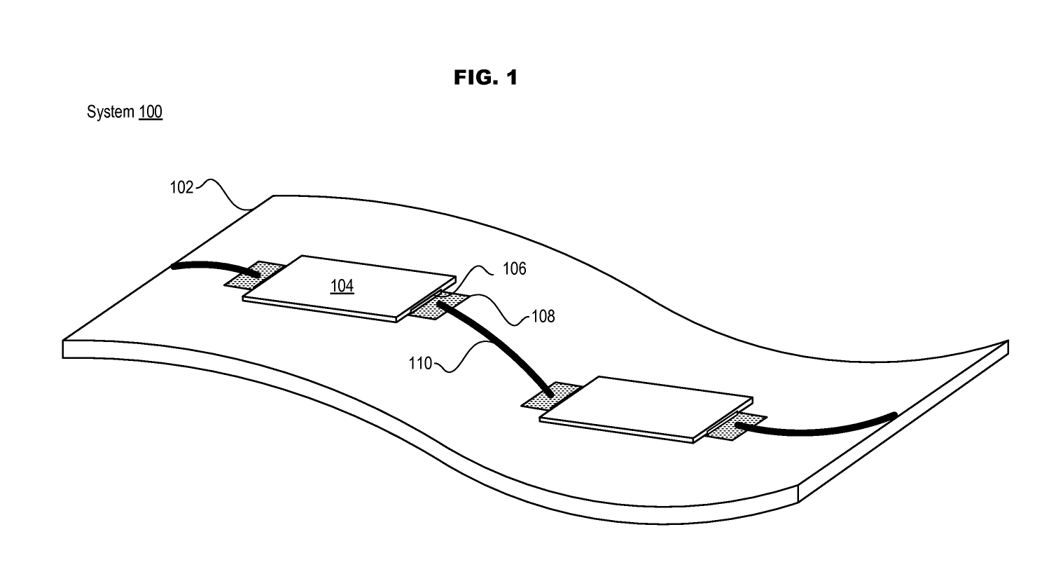

FIG. 1 illustrates an example system for attaching devices to flexible substrates consistent with the present disclosure. System 100 may comprise, for example, substrate 102 on which at least one device 104 may be attached. Substrate 102 may be a flexible substrate based on PET, paper or any other flexible material providing a nonconductive surface on which devices may be mounted. Devices 104 may comprise any type of electrical component. One example of an electrical component consistent with various embodiments of the present disclosure may be a light-emitting diode (LED) in a surface mount package. A plurality of surface mount LEDs may be automatically place on substrate 102 to, for example, form an array of light sources for use in lighting fixtures (e.g., bulbs, fluorescent tube replacements, lamps, flashlights, etc.). Device 104 may comprise at least one conductive pad 106. Conductive pad 106 may electronically couple device 104 to a surface of substrate 102 including, for example, conductors, circuit paths, etc. In the instance of a surface mount LED, device 104 may comprise at least two conductive pads 106.

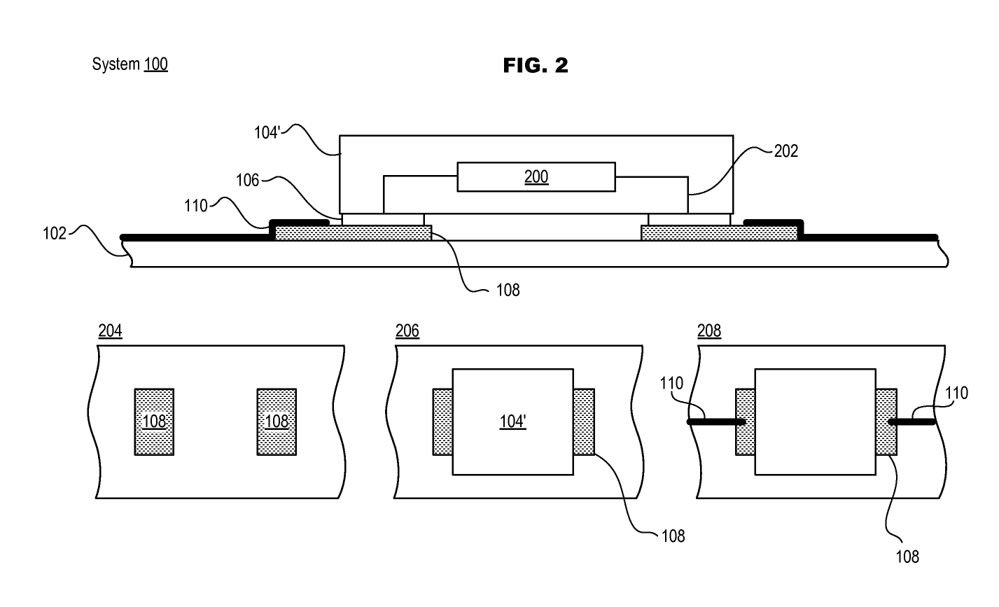

System 100 discloses an example implementation wherein device 104 is attached by conductive pads 106 to substrate 102 using a conductive adhesive 108. For example, conductive adhesive 108 may be a conductive epoxy (e.g., a two-part epoxy including silver for conduction). Conductive adhesive 108 allows device 104 to be permanently affixed to substrate 102 without the need for high temperatures (e.g., as required for solder attachment). Materials like PET and paper cannot withstand solder temperatures, and existing materials impervious to high heat (e.g., polyimide substrates) add substantial expense to manufacturing that is often not feasible for the types of circuitry being manufactured on flexible substrates. As will be disclosed in more detail in FIG. 2, conductive adhesive 108 may be extended beyond the edges of device 104, creating a contact over which conductive ink 110 may be applied. Conductive ink 110 may be applied to substrate 102 to form conductors electronically coupled to device 104. For example, in system 100 a plurality of devices 104 may be coupled in series by conductive ink 110.

FIG. 2 illustrates an example adhesive to conductive ink-based connection consistent with the present disclosure. A side view is shown of system 100 as disclosed in FIG. 1, wherein additional detail is provided with respect to device 104′. Device 104′ may include integrated circuit (IC) 200 (e.g., the actual IC die) coupled to conductive pads 106 by wires or traces 202. Conductive pads 106 may be anchored to substrate 102 by conductive adhesive 108. Conductive ink 110 may then be applied over a portion of conductive adhesive 108. As a result, conductive adhesive 108 may electronically couple conductive pads 106 to conductive ink 110, allowing device 104′ to be electronically coupled to other devices 104′ and/or circuitry on substrate 102.

Example stages of assembly for system 100 are shown at 204 to 206 in FIG. 2. Initially, conductive adhesive 108 may be applied to substrate 102 as illustrated at 204, the area over which conductive adhesive 108 is applied going beyond the anticipated area of device 104′ when attached. This operation is seen more clearly at 206 when device 104′ is attached to substrate 102. It is important to note that in at least one embodiment consistent with the present disclosure substrate 102 may be put through a process to cure conductive adhesive 108. Curing conductive adhesive 108 may remove some of the solvents and/or other chemicals in conductive adhesive 108 that may be caustic to conductive ink 110. As illustrated at 208, conductive ink 110 may then be applied over at least part of the portion of conductive adhesive 108 that exceeds the boundaries of device 104′ to form conductors electronically coupled to device 104′.

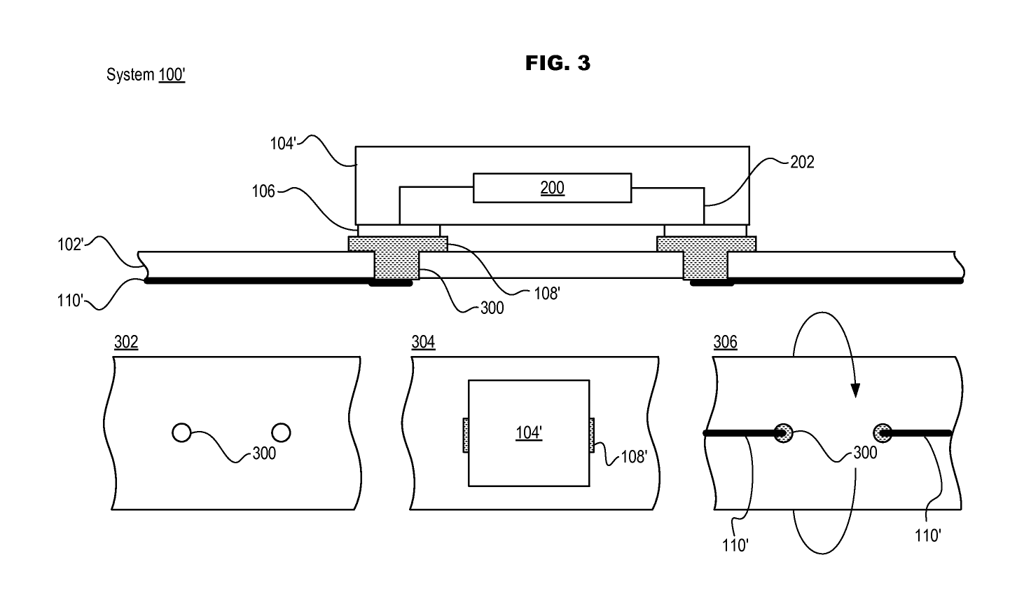

FIG. 3 illustrates an alternative example adhesive to conductive ink-based connection consistent with the present disclosure. System 100′ may include at least one opening 300 formed in substrate 102′. For example, the location of openings 300 may correspond to conductive pads 106 in device 104′. Conductive adhesive 108′ may then be applied to substrate 102′ in an manner to allow conductive adhesive 108′ to both fill openings 300 and to anchor device 104′ to substrate 102′. Given that the surface of substrate 102′ to which device 104′ is attached is the “front” of substrate 102′ and the surface of substrate 102′ opposite to the front is the “back” of substrate 102′, conductive ink 110′ may be applied over conductive adhesive 108′ exposed on the back of substrate 102′ to form conductors electronically coupled to device 104′. The implementation shown in system 100′ may be beneficial in situations where, for example, the available surface area for attaching devices 104′ on the front of substrate 102′ is very limited, where the front of substrate 102′ may be exposed to conditions that may harmful to conductive ink 110′, etc.

Example stages of assembly for system 100′ are shown at 302 to 306 in FIG. 3. Initially, at least one opening 300 may be formed in substrate 102′ as illustrated at 302. For example, openings (e.g., holes) may be drilled, laser cut, etched, etc. through substrate 102′. Conductive adhesive 108′ may then be applied over holes 300, and device 104′ may be attached to substrate 102′ using conductive adhesive 108′ as shown at 304. Conductive adhesive 108′ may both anchor device 104′ to substrate 102′ and also fill openings 300 to a degree that at least some conductive adhesive 108′ is exposed on the back of substrate 108′. In one embodiment the conductive adhesive (e.g., conductive epoxy) may be cured. At 306 conductive ink 110′ may be applied to the back of substrate 102′, conductive ink 110′ being applied over conductive adhesive 108′ exposed through openings 300 to form conductors electronically coupled to device 104′.

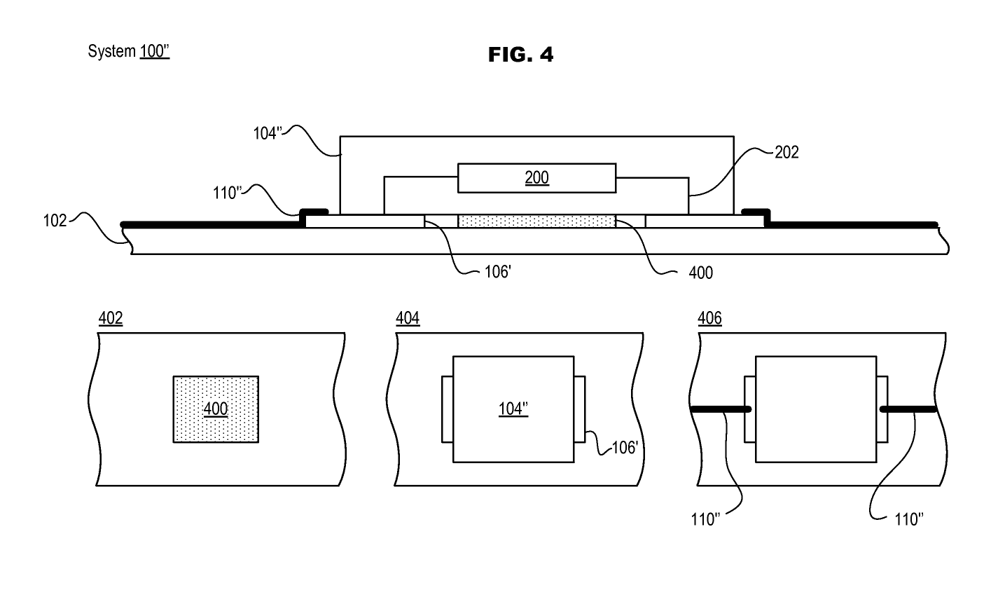

FIG. 4 shows an example device-to-conductive ink-based connection consistent with the present disclosure. In system 100″, device 104″ may comprise at least one conductive pad 106′ that extends beyond an edge of device 104″. A non-conductive adhesive 400 (e.g., non-conductive epoxy) may be utilized to anchor the housing of device 104′ to substrate 102. Conductive ink 110″ may then be applied over at least part of the portion of conductive pads 106′ extending beyond the edge of device 104″, forming conductors that may electronically couple device 104″ to other devices via circuitry on substrate 102. At least one advantage of system 100″ is the exclusion of conductive adhesive. Avoiding the use of conductive adhesive may reduce the overall cost of the assembly and may eliminate the need for curing prior to the application of conductive ink 110″. However, the cost savings may depend on the cost of conductive adhesive versus devices 104″ having modified pads.

Example stages of assembly for system 100″ are shown at 402 to 404 in FIG. 4. Initially, non-conductive adhesive 400 may be applied to substrate 102 as illustrated at 402. Non-conductive adhesive 400 may be applied in an area corresponding to where the housing of device 104″ will be located when attached to substrate 102. The attachment of device 104″ to substrate 102 is disclosed at 404, conductive pads 106′ extending beyond the edge of device 104″. Conductive ink 110″ may then be applied over at least part of the portion of conductive pads 106′ extending beyond the edges of device 104″. In system 100″, when non-conductive adhesive 400 is cured (if necessary) may be independent of the application of conductive ink 110″ since conductive ink 110″ may not come into contact with non-conductive adhesive 400.

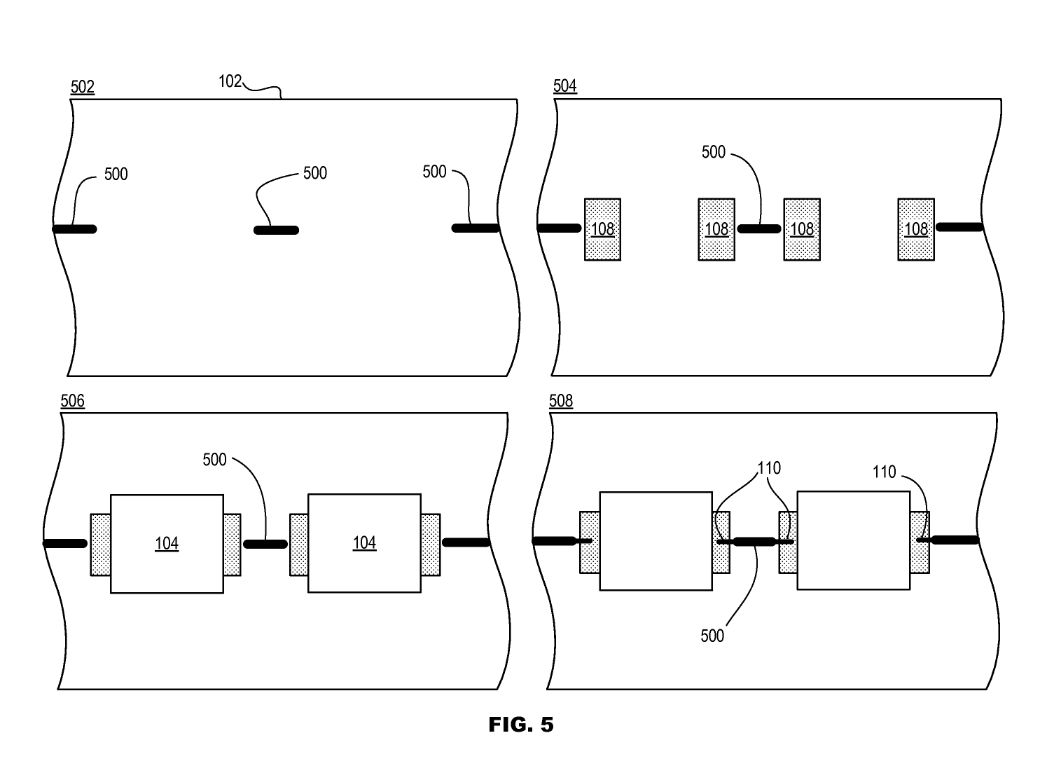

FIG. 5 an example of circuit path to device bridging consistent with the present disclosure. In at least one embodiment, a circuit path (e.g., conductive traces for coupling devices 104 attached to substrate 102) may be at least partially applied to substrate 102 prior to devices 104 being attached. Example stages of assembly are shown at 502 to 508. For example, circuit path 500 is shown pre-printed on substrate 102 at 502. Circuit path 500 may be pre-printed in conductive ink using an automated process such as, for example, silk screening, printing, plotting, etc. Using the system 100 as illustrated in FIG. 1 as an example, conductive adhesive 108 may then be applied to substrate 102 at 504. Conductive adhesive may be applied in a manner so as not to come into contact with circuit path 500. As shown at 506, devices 104 may then be applied to substrate 102, conductive adhesive 108 being employed to anchor at least one conductive pad 106 in device 104 to substrate 102. In one embodiment, conductive adhesive 108 may then be cured prior to the application of conductive ink 110. As shown at 508, conductive ink 110 may be applied to over at least part of conductive adhesive 108 and circuit path 500 to create conductors coupling device 104 to circuit path 500. It is important to note that while circuit path 500 is shown in a configuration that couples devices 104 in series, this example configuration is merely for the sake of explanation. Embodiments consistent with the present disclosure may include substantially more complex circuit paths 500 configured based on, for example, the application for which the circuitry is intended. Moreover, the example shown in FIG. 5 may be implemented with any of the systems disclosed in FIG. 2-4.

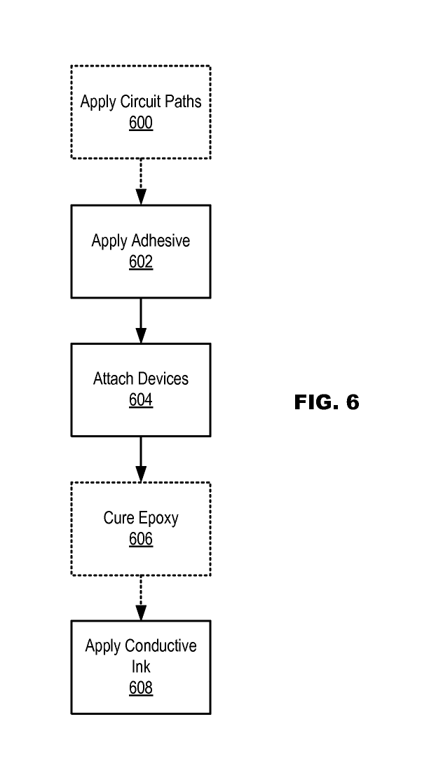

FIG. 6 illustrates example operations for a system for attaching devices to flexible substrates consistent with the present disclosure. In operation 600 circuit paths may be applied to a substrate (e.g., may be pre-printed on the substrate in conductive ink). Operation 600 may be optional in that all required circuit paths may be created later simply through application of conductive ink (e.g., in operation 608). In operation 602 adhesive (e.g., epoxy) may be applied to the substrate. Whether the adhesive is conductive or non-conductive depends on the type of system being utilized (e.g., such as previously disclosed in FIG. 2-4). In operation 604 devices may be attached to the substrate. For example, the substrate may be run through an automated pick-and-place process through which surface mount devices are applied to the substrate. In optional operation 606 curing may take place to set the adhesive that was applied in operation 602. Curing may be required when, for example, a conductive epoxy-based system is being utilized, and curing of the conductive epoxy may be necessary to eliminate solvents and/or other chemicals in the conductive epoxy that may be harmful to conductive ink. In operation 608 conductive ink may be applied to the substrate. For example, conductive ink may be printed, plotted, sprayed, etc. onto the substrate to form conductors electronically coupled to the device.

While FIG. 6 illustrates various operations according to an embodiment, it is to be understood that not all of the operations depicted in FIG. 6 are necessary for other embodiments. Indeed, it is fully contemplated herein that in other embodiments of the present disclosure, the operations depicted in FIG. 6, and/or other operations described herein, may be combined in a manner not specifically shown in any of the drawings, but still fully consistent with the present disclosure. Thus, claims directed to features and/or operations that are not exactly shown in one drawing are deemed within the scope and content of the present disclosure.

As used in this application and in the claims, a list of items joined by the term “and/or” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrases “at least one of A, B or C” can mean A; B; C; A and B; A and C; B and C; or A, B and C.

The terms “electronically coupled,: “electrically coupled,” and the like as used herein refers to any connection, coupling, link or the like by which electrical signals and/or power carried by one system element are imparted to the “coupled” element. Such “electronically coupled” devices, or signals and devices, are not necessarily directly connected to one another and may be separated by intermediate components or devices that may manipulate or modify such signals. Likewise, the terms “connected” or “coupled” as used herein in regard to mechanical or physical connections or couplings is a relative term and does not require a direct physical connection.

Thus, this disclosure is directed to a system for attaching devices to flexible substrates. A device may be coupled to a flexible substrate in a manner that prevents adhesive from contacting conductive ink while the adhesive is harmful. If conductive epoxy is used to anchor conductive pads in the device to the flexible substrate, conductive epoxy may be applied beyond the edge of the device over which conductive ink may be applied to make electrical connections. Holes may also be formed in the flexible substrate allowing conductive epoxy to be exposed on a surface of the flexible substrate opposite to the device location, the conductive ink connections being made on the opposite surface. The conductive ink may also be applied directly to the conductive pads when extended beyond the device's edge. The flexible substrate may be pre-printed with circuit paths, the conductive ink connecting the device with the circuit paths.

According to one aspect there is provided circuitry. The circuitry may include a flexible substrate, at least one device coupled to the flexible substrate, adhesive applied to the flexible substrate to couple the at least one device to the flexible substrate; and conductive ink applied to the flexible substrate to form conductors electronically coupled to the at least one device, the conductive ink being applied after the adhesive.

According to another aspect there is provided a method. The method may include applying adhesive to a flexible substrate, coupling at least one device comprising at least one conductive pad to the substrate using the adhesive and applying conductive ink to the flexible substrate to form conductors electronically coupled to the at least one device.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

What is claimed is:

1. Circuitry, comprising:
a flexible substrate;
at least one device coupled to the flexible substrate;
adhesive applied to the flexible substrate to couple the at least one device to the flexible substrate; and
conductive ink applied to the flexible substrate to form conductors electronically coupled to the at least one device, the conductive ink being applied after the adhesive.

2. The circuitry according to claim 1, wherein the adhesive is cured before the conductive ink is applied to the flexible substrate.

3. The circuitry according to claim 1, wherein the at least one device comprises at least one conductive pad and the adhesive is conductive epoxy anchoring the at least one device to the flexible substrate by adhering the at least one conductive pad to the flexible substrate.

4. The circuitry according to claim 3, wherein the conductive epoxy is applied to the flexible substrate so that at least a portion of the conductive epoxy is exposed beyond an edge of the at least one device when coupled to the flexible substrate and wherein the conductive ink is applied over at least part of the exposed portion of the conductive epoxy to form conductors electronically coupled to the at least one device.

5. The circuitry according to claim 3, wherein the flexible substrate comprises an opening formed in a location on a surface of the flexible substrate corresponding to the at least one conductive pad when the at least one device is coupled to the flexible substrate, the opening traversing from the surface to an opposite surface of the flexible substrate, the conductive epoxy being applied to the flexible substrate to fill the opening so that the conductive epoxy is exposed on the opposite surface of the flexible substrate when the at least one device is coupled to the flexible substrate and wherein the conductive ink is applied to the opposite surface of the flexible substrate and over the exposed conductive epoxy to form conductors electronically coupled to the at least one device.

6. The circuitry according to claim 1, wherein the at least one device comprises at least one conductive pad including a portion extending beyond an edge of the at least one device and the adhesive is non-conductive epoxy.

7. The circuitry according to claim 6, wherein the conductive ink is applied over at least part of the portion of the at least one conductive pad extending beyond the edge of the at least one device to form conductors electronically coupled to the at least one device.

8. The circuitry according to claim 1, further comprising at least one circuit path printed on the flexible substrate, the conductors coupling the at least one printed circuit path to the at least one device.

9. A method, comprising:
applying adhesive to a flexible substrate;
coupling at least one device comprising at least one conductive pad to the substrate using the adhesive; and
applying conductive ink to the flexible substrate to form conductors electronically coupled to the at least one device.

10. The method according to claim 9, further comprising:
curing the adhesive before applying the conductive ink to the flexible substrate.

11. The method according to claim 9, wherein:
the adhesive is conductive epoxy; and
applying conductive ink to the flexible substrate comprises applying conductive ink over at least part of a portion of the conductive epoxy exposed beyond an edge of the at least one device to form conductors electronically coupled to the at least one device.

12. The method according to claim 9, wherein:
the adhesive is non-conductive epoxy; and
applying conductive ink to the flexible substrate comprises applying conductive ink over at least part of a portion of the at least one conductive pad exposed beyond an edge of the at least one device to form conductors electronically coupled to the at least one device.

13. The method according to claim 9, further comprising:
forming an opening in a location on a surface of the flexible substrate corresponding to the at least one conductive pad when the at least one device is coupled to the flexible substrate, the opening traversing from the surface to an opposite surface of the flexible substrate;
applying conductive epoxy to the flexible substrate to fill the opening so that the conductive epoxy is exposed on the opposite surface of the flexible substrate when the at least one device is coupled to the flexible substrate; and
applying conductive ink to the opposite surface of the flexible substrate and over the exposed conductive epoxy to form conductors electronically coupled to the at least one device.

14. The method according to claim 9, further comprising:
printing at least one circuit path on the flexible substrate, the conductors coupling the at least one printed circuit path to the at least one device.
